(19) United States
(12) Patent Application Publication
(10) Pub. No.: US 2012/0043128 A1
(43) Pub. Date: Feb. 23, 2012

(54) Printed circuit board and method of manufacturing the same

(75) Inventors: Kyoung Ro Yoon, Daejeon (KR); Joung Gul Ryu, Seoul (KR); Young Hwan Shin, Daejeon (KR)

(73) Assignee: SAMSUNG ELECTRO-MECHANICS CO., LTD., Suwon (KR)

(21) Appl. No.: 13/064,657

(22) Filed: Apr. 6, 2011

(30) Foreign Application Priority Data
Aug. 18, 2010 (KR) 10-2010-0079831

(51) Int. Cl. H05K 1/11; H05K 3/42

(52) U.S. Cl. 174/266; 29/852

(57) ABSTRACT

The present invention provides a multilayer printed circuit board and a method for manufacturing the same. The printed circuit board includes: an inner circuit layer which is disposed on a first insulating layer; a via land which is disposed on the first insulating layer to be spaced apart from the inner circuit layer and has a hole; a second insulating layer which is disposed on the first insulating layer including the inner circuit layer and the via land; first and second outer circuit layers which are disposed on outer surfaces of the first and second insulating layers, respectively; and a via which passes through the hole of the via land and the first and second insulating layers and electrically interconnects the first and second outer circuit layers.

### CROSS-REFERENCE TO RELATED APPLICATIONS

This application claims the benefit of Korean Patent Application No. 10-2010-0079831 filed with the Korea Intellectual Property Office on Aug. 18, 2010, the disclosure of which is incorporated herein by reference.

### BACKGROUND OF THE INVENTION

1. Field of the Invention

The present invention relates to a multilayer printed circuit board and a method of manufacturing the same; and, more particularly, to a multilayer printed circuit board provided with a via land for penetration of a via and a method of manufacturing the same.

2. Description of the Related Art

Electronic devices have recently been developed to be compact enough to be portable, as well as to incorporate high functions and communication functions, .e.g., internet, transmission and reception of data including moving images, and mass data. This causes a more complicated design of a printed circuit board (PCB) and an increasing demand for high-density and down-sized circuits. Thus, a PCB mounted on an electronic device becomes smaller and thinner, and a line width of circuit wires on the PCB gets narrower as well, for implementing functions of the PCB. Also, the PCB has been manufactured to be in a multiple layer instead of a single layer.

In a multilayer PCB, for interlayer connection, there may be formed a via which passes through insulating layers. Hereinafter, a method for forming the via will be made as follows. First, a via hole is formed by using a drill, followed by formation of an inner circuit layer and lamination of an insulating material, and then the inside of the resultant via hole is subjected to a plating process or a filling process of a conductive material, so that it is possible to form a via. Herein, in the middle of forming the via, a resin smear may be formed on the bottom of the via hole. The resin smear may reduce contact force between the inside of the via hole and the via. At this time, the reduction in contact force between the via and the via hole may make the via detached from the inside of the via hole, which is referred to as via's open failure. The via's open failure may reduce reliability of electronic devices equipped with a PCB, and further cause electrical connection failure of the electronic devices.

### SUMMARY OF THE INVENTION

The present invention has been proposed in order to overcome the above-described problems and it is, therefore, an object of the present invention to provide a multilayer printed circuit board which is provided with a via land for penetration of the via to thereby prevent via's open failure, and a method for manufacturing the same.

In accordance with one aspect of the present invention to achieve the object, there is provided a printed circuit board including: an inner circuit layer which is disposed on a first insulating layer; a via land which is disposed on the first insulating layer to be spaced apart from the inner circuit layer and has a hole; a second insulating layer which is disposed on the first insulating layer including the inner circuit layer and the via land; first and second outer circuit layers which are disposed on outer surfaces of the first and second insulating layers, respectively; and a via which passes through the hole of the via land and the first and second insulating layers and electrically interconnects the first and second outer circuit layers.

Also, the via has a diameter which gets larger toward the outer surfaces of the first and second insulating layers on the basis of the hole of the via land.

Also, the hole has a diameter in a range from 10 to 100 μm.

Also, the via is formed by a fill plating.

Also, the via land is disposed around the via to be formed to wrap the via.

Also, the printed circuit board further includes a plated through hole which has a diameter larger than that of the via hole, and through which the first and second outer circuit layers are electrically interconnected.

Also, the via land and the inner circuit layer are formed of the same material as each other.

In accordance with another aspect of the present invention to achieve the object, there is provided a method for manufacturing a printed circuit board including the steps of: forming a via land with a hole and an inner circuit layer on a first insulating layer; stacking a second insulating layer on the first insulating layer including the via land and the inner circuit layer; forming a first via hole which exposes the hole of the via land, at the first insulating layer; forming a second via hole which is communicated with the first via hole and exposes the via land, at the second insulating layer; and forming a via provided in the hole of the via land and in the first and second via holes, and first and second circuit layers provided on the outer surfaces of the first and second insulating layers, the first and second circuit layers being interconnected through the via.

Also, the via is formed by performing a fill plating for the insides of the first and second via holes, and for the hole of the via land.

Also, the first and second via holes each are formed by a laser processing.

Also, each of the first and second via holes is formed to have a diameter which gets larger toward an outer side from a center.

Also, the hole of the via land is formed to have a diameter smaller than those of the first and second via holes.

Also, the method further includes a step of forming a through hole which passes through both the first and second insulating layers, before or after the step of forming the first and second via holes, and the step of forming the via, and the first and second outer circuit layers further includes a step of forming a plating layer at an inner wall of the through hole.

Also, in the step of forming any one of the first and second via holes, a blind via hole which exposes the inner circuit layer is further formed, and in the step of forming the via, and the first and second outer circuit layers, a blind via filled in the blind via hole is further formed.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view showing a printed circuit board in accordance with a first embodiment of the present invention; and

FIGS. 2 to 6 are cross-sectional views for explaining a process of manufacturing the printed circuit board in accordance with a second embodiment of the present invention, respectively.

### DETAILED DESCRIPTION OF THE PREFERABLE EMBODIMENTS

Embodiments of a multilayer printed circuit board in accordance with the present invention will be described in detail with reference to the accompanying drawings. When describing them with reference to the drawings, the same or corresponding component is represented by the same reference numeral and repeated description thereof will be omitted.

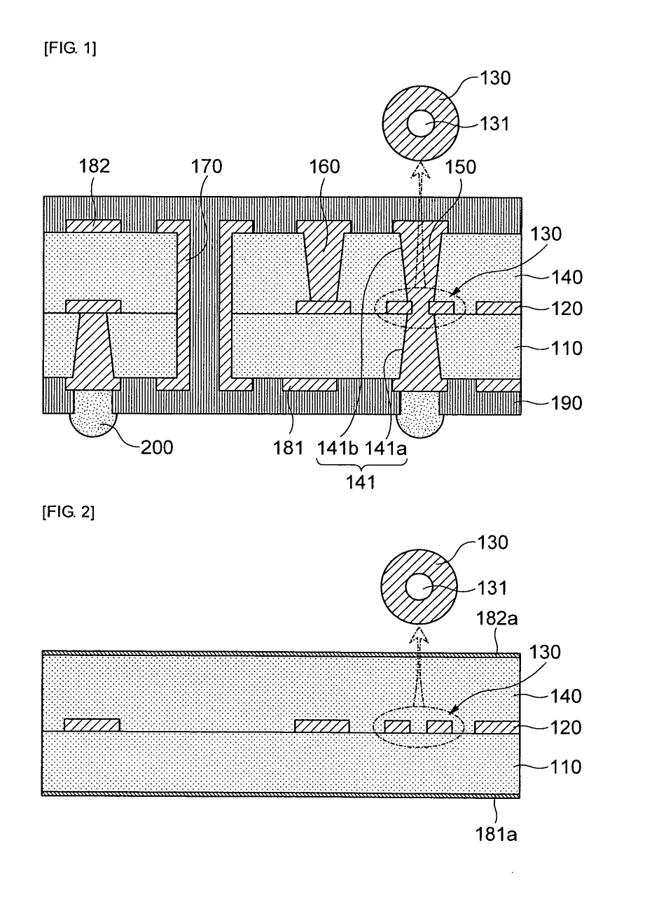

FIG. 1 is a cross-sectional view showing a printed circuit board in accordance with a first embodiment of the present invention.

Referring to FIG. 1, the printed circuit board according to the first embodiment of the present invention may include an inner circuit layer 120, a via land 130, a second insulating layer 140, first and second outer circuit layers 181 and 182, and a via 150. The inner circuit layer 120 and the via land 130 are disposed on the first insulating layer 110, and the second insulating layer 140 covers the inner circuit layer 120 and the via land 130. The first and second outer circuit layers 181 and 182 are disposed on outer surfaces of the first and second insulating layers 110 and 140, respectively. The via 150 is electrically connected to the first and second outer circuit layers 181 and 182 through the via land 130.

Herein, the first and second insulating layers 110 and 140 may be provided with the via hole 141 which passes through a hole of the via land 130. At this time, the via hole 141 may be provided on each of the first and second insulating layers 110 and 140, and the via hole 141 may include the first and second via holes 141a and 141b which are interconnected through the hole 131 of the via land 130. Since each of the first and second via holes 141a and 141b may have a diameter which gets smaller toward the center from the outside, in case where the via 150 is formed by the plating process, a fill plating process may be performed with ease. Thus, the via 150 formed by being filled in the first and second via holes 141a and 141b may have a diameter which gets larger toward the outer surface of each of the first and second insulating layers 110 and 140 from the center of the hole 131 of the via land 130. For example, the via 150 may be shaped like a sandglass.

Also, the diameter of the hole 131 may be formed to be within a range of 10 to 100 μm, in consideration of ease of the fill plating process and possibility of the hole processing process in forming the via 150. That is, in case where the hole 131 has a diameter of less than 10 μm, the hole processing process may be difficult to perform, and a resin smear may remain on the via land 130 around the hole 131. Therefore, adhesive force may be reduced between the via land 130 and the via 150. On the other hand, in case where the hole 131 has a diameter of more than 100 μm, it may spend a longer time to perform the fill plating process for forming the via 150, and thus mass-production may be reduced. Also, an amount of the filled plating materials is increased, and thus production cost per unit may be increased.

Also, the via 150 may be formed to pass through the hole 131 of the via land 130, and the via land 130 may be formed around the via 150. That is, the via land 130 may be formed to wrap the via 150. Herein, since the via land 130 may be formed of the same metal as that of the inner circuit layer 120, the adhesive force between the via 150 and the via land 130 may be secured.

Moreover, since the hole 131 of the via land 130 may be formed to have a smaller diameter than that of the via hole 141, the via land 130 may be partially protruded from the inner wall of the via hole 141. Herein, the via filled in the via hole may be formed in such a manner to cover surfaces of ends where the hole of the via land 130 is formed, as well as even a part of the upper and lower portions. Thus, the contact area of the via 150 and the via land 130 may be increased, and thus the bonding area between the via 150 and the via land 130 may be increased as well.

As such, as the bonding force between the via 150 and the via land 130 is increased, the bonding force between the via hole 141 and the via 150 may be improved, and thus reliability may be secured in bonding the via and the via land.

In addition, the printed circuit board may include a plating through hole 143 which passes through both of the first and second insulating layers 110 and 140 and electrically connects first and second outer circuit layers 181 and 182. Herein, the plating through hole 143 may have an upside diameter larger than an upside diameter of the via hole 141. This is because when the via is required to be above a predetermined diameter (e.g., 100 μm), it is preferable to form the plating through hole 143 for improving productivity.

Also, the printed circuit board may further include a blind via 160 through which the inner circuit layer 120 is electrically connected to any one of the first and second outer circuit layers 181 and 182.

Also, the first and second insulating layers 110 and 140 may be formed of a polypropylene glycol (PPG). However, the present invention is not limited by the materials of the first and second insulating layers 110 and 140.

Also, the printed circuit board may further include a solder resist layer 190 which covers the first and second outer circuit layers 181 and 182. The solder resist layer 190 may be provided with opening which exposes a pad included in any one of the first and second outer circuit layers 181 and 182.

Also, an external connection means 200 (e.g., solder ball or bump) which electrically connects the outside may further be formed on the pad exposed by the opening of the solder resist layer 190.

Therefore, as in the embodiment of the present invention, as the via land with the hole is, provided, the bottom surface of the via hole where the resin smear may remain may be removed, and thus it is possible to implement a design structure for preventing occurrence of any resin smear. Thus, it is possible to prevent open-failure of the via due to occurrence of the resin smear.

Also, as the printed circuit board is formed to have a via hole whose diameter gets larger toward both outer sides from the center of the via hole, it is possible to implement a design structure for increasing plating filling density in a fill plating process for formation of vias, and thus to improve reliability in connecting vias.

Also, the printed circuit board includes a via land which is formed to wrap the via, so that it is possible to increase a contact strength between the via land and the via, and thus to improve reliability of via connection.

Hereinafter, a process of manufacturing a printed circuit board according to a second embodiment of the present invention will be described with reference to FIGS. 2 to 6.

FIGS. 2 to 6 are cross-sectional views showing a process of manufacturing the printed circuit board in accordance with the second embodiment of the present invention, respectively.

Referring to FIG. 2, in order to manufacture the printed circuit board, the inner circuit layer 120 and the via land 130 with the hole 131 provided therein are formed on the first insulating layer 110.

In particular, in order to form the inner circuit layer 120 and the via land 130 on the first insulating layer 110, a carrier substrate (not shown) with releasing layers 181a formed on both surfaces thereof is provided. Thereafter, the first insulating layer 110 and the metal layer are formed on the releasing layers 181a, respectively. At this time, the releasing layers 181a and the first insulating layer 110 may be bonded to each other. Thereafter, by performing an etching process for the metal layer, the inner circuit layer 120 and the via land 130 with the hole 131 may be formed. Herein, the diameter of the hole 131 may be formed to have a range from 10 to 100 μm, in consideration of ease of the fill plating process and possibility of the hole processing process for formation of the via 150.

Thereafter, a second insulating layer 140 and a metal thin layer 182a are stacked on the first insulating layer 110 with the inner circuit layer 120 and the via land 130. Herein, while being boned to each other, both the second insulating layer 140 and the metal thin layer 182a may be stacked on the first insulating layer 110.

Thereafter, by separating the releasing layer 181a from the carrier substrate, there may be simultaneously manufactured two preliminary printed circuit boards 100a one of which includes the releasing layer 181a, the first insulating layer 110, the inner circuit layer 120, and the via land 130, and the other of which includes the second insulating layer 140, and the metal thin layer 182a. Herein, since the releasing layer 181a may be formed of a metal, the releasing layer 181a may play a role of increasing a bonding force between the insulating layer and the circuit layer, or of a seed layer for the plating process in the subsequent process.

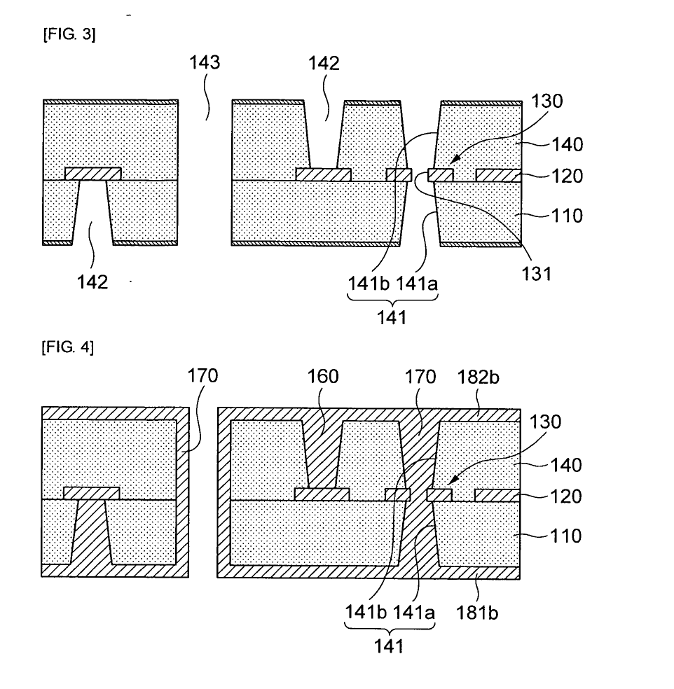

Referring to FIG. 3, after the formation of the preliminary printed circuit boards 100a, the via hole 141 which passes through the first and second insulating layers 120 and 140 through the hole 131 of the via land 130 may be formed.

A detailed description will be given of a method for forming the via hole 141. The first via hole 141a which exposes the hole 131 of the via land 130 is formed on the first insulating layer 110. Herein, the first via hole 141a may be formed by being subjected to a laser processing. At this time, the first via hole 141a may be formed to have a diameter which gets larger toward the outer layer of the first insulating layer 110 from the via land 130. For example, the cross-section of the first via hole 141a may be formed in a trapezoid shape. The method for forming the first via hole 141a in the trapezoid shape may be made by scanning a first laser for the first insulating layer 110 in such a manner that the center of the hole 131 is exposed, and then scanning a second laser with a lower output than that of the first laser for both sides of the scanned point of the first laser.

Thereafter, the second via hole 141b which exposes the hole 131 of the via land 130 may be formed on the second insulating layer 140. Herein, the second via hole 141b may be formed to have a diameter which gets larger toward the outer layer of the second insulating layer 140, above thee via land 130. For example, the cross-section of the second via hole 141b may be formed in an inverted trapezoid shape. Herein, the method for forming the second via hole 141b in the inverted trapezoid shape may be made by the above-mentioned method for forming the first via hole 141a.

Herein, the second via hole 141b and the first via hole 141a may be communicated with each other through the hole of the via land 130. Thus, there may be formed the via hole 141 which passes through the first and second insulating layers 110 and 140 through the first and second via holes 141a and 141b. At this time, the via hole 141 may have a diameter which gets larger toward both sides from the center thereof by the combination of the trapezoid-shaped first via hole 141a and the inverted trapezoid-shaped second via hole 141b. For example, the via hole 141 may be formed in a sandglass shape. Thus, the fill plating process may be easily performed for the via hole in the subsequent process. This is because the center of the via is narrow and thus filling by plating materials may be made from the center of the via to the entire via hole, which results in easier and faster fill plating processes.

Also, the diameter of the via hole 141 may be formed to be larger than that of the hole 131 of the via land. Thus, the via 150 formed in the subsequent process is formed to cover the etched surfaces of the via land 130 which forms the hole 131, so the contact area between the via 150 and the via land 130 may be increased. Therefore, it is possible to increase the adhesive force between the via 150 and the via land 130.

In addition, in the process for forming the first via hole 141a and the second via hole 141b, the blind via hole 142 for exposing the inner circuit layer 120 may further be formed.

Also, when the via hole 141 is formed and then a via with a larger diameter than that of the formed via hole 141 is formed, the through hole 143 which passes through both the first and second insulating layers 110 and 140 may be formed, so as to reduce production's cost.

Referring to FIG. 4, after the formation of the via hole 141, the via is formed by performing the fill plating process for the inside of the via hole 141, and simultaneously the first and second plating layers 181b and 182b disposed at the outer surfaces of the first and second insulting layers 110 and 140 are formed.

Herein, the via 150 may be formed in the shape of the via hole 141, such as a sandglass. Also, the via 150 may be formed through the hole of the via land 130. At this time, as the hole 131 of the via land 130 is formed, any resin smear may be prevented from being generated, and thus open-failure of the via 150 due to the resin smear may be prevented. Also, as the via 150 is formed to pass through the hole 131 of the via land, the via land 130 may be formed around the via 150. Therefore, it is possible to secure adhesive force of the via 150 within the via hole 141. This is because as the via land 130 is formed of the same conductive material as that of the inner circuit layer 120, for example, a metal like Cu, the via land 130 and the via 150 formed by the plating process may have high adhesive force therebetween.

Also, the first and second plating layers 181b and 182b formed on the outer surfaces of the first and second insulating layers 110 and 140 may be electrically interconnected through the via 150.

In addition, the plated through hole 170 may be formed on the inner wall of the through hole 143 which passes through the first and second insulating layers 110 and 140 in the fill plating process.

Herein, the plated through hole 170 may play a role of electrical interconnection of the first and second plating layers 181b and 182b. Also, the blind via hole 142 is filled with the conductive material in the fill plating process to thereby form the blind via 160. Herein, the inner circuit layer 120 and the first plating layer 181b, or the inner circuit layer 120 and the second plating layer 182b may be electrically interconnected through the blind via 160.

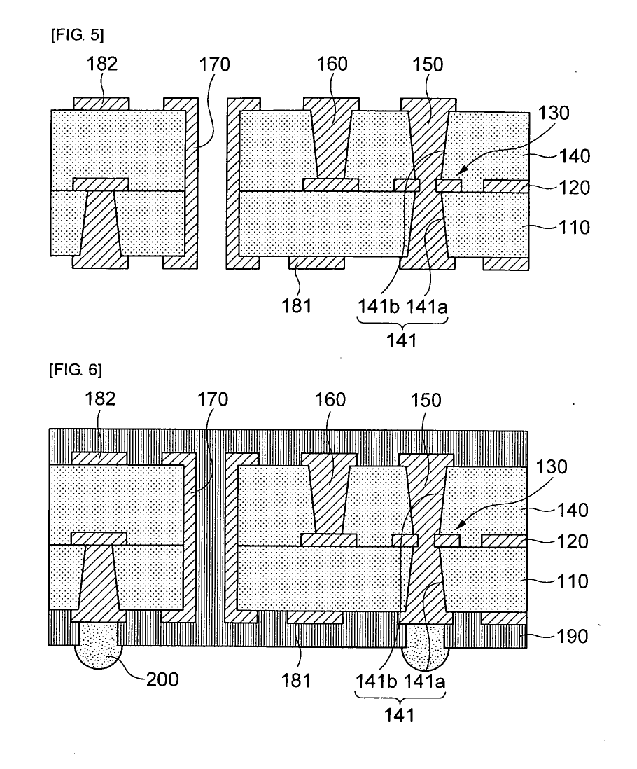

Referring to FIG. 5, by etching the first and second plating layers 181b and 182b, the first and second outer circuit layers 181 and 182 may be formed. Herein, the etching of the first and second plating layers 181b and 182b may be selectively performed by using the resist pattern. The resist pattern may be formed by forming a resist layer through attachment of a dry film or through coating of photo-sensitive resin and then performing exposure and developing processes for the formed resist layer. The resist pattern may be removed after the etching process is completed.

Herein, the first and second plating layers 181b and 182b may be electrically interconnected through the via 150 or through the plated through hole 170, and thus the first and second outer circuit layers 181 and 182 formed by etching the first and second plating layers 181 b and 182b may be electrically interconnected as well through the via 150 or through the plating through hole 170.

Referring to FIG. 6, the solder resist layer may be formed on the first and second outer circuit layers 181 and 182. Thereafter, opening to expose a pad included in at least one of the first and second outer circuit layers 181 and 182 is formed.

Thereafter, the external connection means (e.g., solder ball or bump) is formed on the pad exposed by the opening of the solder resist layer 190, so that it is possible to form the printed circuit board 100 which can secure connection reliability of the via.

Therefore, as in the embodiment of the present invention, the via land with the hole is formed in the process for forming the inner circuit layer, and then the process of forming the via is performed, thereby preventing any resin smear from being generated. Therefore, it is possible to prevent open-failure of via due to the resin smear.

Also, as the via hole of the printed circuit board of the present invention is formed to have a diameter which gets larger toward the both outer surfaces from the center of the via hole, it is possible to increase plating filling density in the fill plating process for formation of the via, which results in improvement of connection reliability of the via.

Also, as the printed circuit board of the present invention has a via land which is formed to wrap the via land, contact strength between the via land and the via may be increased, and thus connection reliability of the via may be improved.

In the printed circuit board of the present invention, the via land with the through hole is formed, and then a via for interlayer connection is formed through the through hole, so that any resin smear which may remain on the bottom surface of the via hole can be prevented from being generated. Therefore, the present invention has advantages of preventing open-failure of via due to occurrence of the resin smear.

Also, in the printed circuit board of the present invention, as the via hole is formed to have a diameter which gets larger and larger toward both outer sides from the center thereof, plating filling density can be increased in the fill plating process for formation of the via, and thus connection reliability of the via can be improved.

Also, in the printed circuit board of the present invention, as the via land is formed to wrap the via, contact strength between the via land and the via can be increased, and thus connection reliability of the via can be improved.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

1. A printed circuit board comprising:
an inner circuit layer which is disposed on a first insulating layer;
a via land which is disposed on the first insulating layer to be spaced apart from the inner circuit layer and has a hole;
a second insulating layer which is disposed on the first insulating layer including the inner circuit layer and the via land;
first and second outer circuit layers which are disposed on outer surfaces of the first and second insulating layers, respectively; and
a via which passes through the hole of the via land and the first and second insulating layers and electrically interconnects the first and second outer circuit layers.

2. The printed circuit board of claim 1, wherein the via has a diameter which gets larger toward the outer surfaces of the first and second insulating layers on the basis of the hole of the via land.

3. The printed circuit board of claim 1, wherein the hole has a diameter in a range from 10 to 100 μm.

4. The printed circuit board of claim 1, wherein the via is formed by a fill plating.

5. The printed circuit board of claim 1, wherein the via land is disposed around the via to be formed to wrap the via.

6. The printed circuit board of claim 1, further comprising a plated through hole which has a diameter larger than that of the via hole, and through which the first and second outer circuit layers are electrically interconnected.

7. The printed circuit board of claim 1, wherein the via land and the inner circuit layer are formed of the same material as each other.

8. A method for manufacturing a printed circuit board comprising the steps of:
forming a via land with a hole and an inner circuit layer on a first insulating layer;
stacking a second insulating layer on the first insulating layer including the via land and the inner circuit layer;
forming a first via hole which exposes the hole of the via land, at the first insulating layer;
forming a second via hole which is communicated with the first via hole and exposes the via land, at the second insulating layer; and
forming a via provided in the hole of the via land and in the first and second via holes, and first and second circuit layers provided on the outer surfaces of the first and second insulating layers, the first and second circuit layers being interconnected through the via.

9. The method of claim 8, wherein the via is formed by performing a fill plating for the insides of the first and second via holes, and for the hole of the via land.

10. The method of claim 8, wherein the first and second via holes each are formed by a laser processing.

11. The method of claim 8, wherein each of the first and second via holes is formed to have a diameter which gets larger toward an outer side from a center.

12. The method of claim 8, wherein the hole of the via land is formed to have a diameter smaller than those of the first and second via holes.

13. The method of claim 8, further comprising forming a through hole which passes through both the first and second insulating layers, before or after the forming the first and second via holes, and wherein the forming the via, and the first and second outer circuit layers further comprises forming a plating layer at an inner wall of the through hole.

14. The method of claim 8, wherein, in the forming any one of the first and second via holes, a blind via hole which exposes the inner circuit layer is further formed, and in the forming the via, and the first and second outer circuit layers, a blind via filled in the blind via hole is further formed.
